(19) United States
(12) Patent Application Publication
(10) Pub. No.: US 2018/0217505 A1
(43) Pub. Date: Aug. 2, 2018

(54) METHOD FOR INSPECTING MASK PATTERN, METHOD FOR MANUFACTURING MASK, AND METHOD FOR MANUFACTURING SEMICONDUCTOR DEVICE

(71) Applicant: Renesas Electronics Corporation, Tokyo (JP)

(72) Inventor: Seiji MATSUURA, Ibaraki (JP)

(73) Assignee: Renesas Electronics Corporation, Tokyo (JP)

(21) Appl. No.: 15/826,933

(22) Filed: Nov. 30, 2017

(30) Foreign Application Priority Data
Jan. 31, 2017 (JP) 2017-015498

(51) Int. Cl. G03F 7/20; G06F 17/50

(52) U.S. Cl. CPC G03F 7/705; G03F 7/70525; G06F 17/5009

(57) ABSTRACT

To shorten a time required for a risk degree determination in a lithography compliance check. When each detection point extracted in a lithography compliance check is categorized, a vertically long detection area and a horizontally long detection area both centering on the detection point are provided for each detection point. Further, a plurality of detection points are categorized based on the identity of each pattern included in the vertically long detection area and the identity of each pattern included in the horizontally long detection area.

### CROSS-REFERENCE TO RELATED APPLICATIONS

The disclosure of Japanese Patent Application No. 2017-015498 filed on Jan. 31, 2017 including the specification, drawings and abstract is incorporated herein by reference in its entirety.

### BACKGROUND

The present invention relates to a method for inspecting a mask pattern, a method for manufacturing a mask, and a method for manufacturing a semiconductor device, and to a technology of a lithography compliance check, for example.

There has been shown in, for example, Patent Document 1, a pattern inspecting method of extracting hazardous patterns in which a difference in shape between a target pattern to be formed over a wafer and a transfer pattern of a mask is large, classifying them for each shape to thereby automatically select a representative pattern. Specifically, first, an area on the mask is divided into a plurality of small areas and thereafter a target pattern and a transfer pattern are compared for each small area to thereby extract coordinate values of hazardous points. Thereafter, of the extracted coordinate values, the coordinate values positioned in a peripheral part of the small area are eliminated as a pseudo hazardous point. Hazardous patterns are selected based on the remaining coordinate values. The hazardous patterns are classified for each shape to determine a representative pattern.

### RELATED ART DOCUMENTS

### Patent Document

[Patent Document 1] Japanese Unexamined Patent Publication Laid-open No. 2007-266391

### SUMMARY

For example, when a semiconductor device to which a technology node of 90 nm or less is applied is developed/manufactured, a simulation called a lithography compliance check (abbreviated as LCC in the specification) or the like is performed prior to the manufacture of a patter transfer original plate (photomask). LCC is a process of preventing flowing out of a photomask including each pattern causing a manufacture failure and a reduction in yield, by performing a simulation in advance with a mask pattern or a mask pattern after an optical proximity correction (OPC) as an object.

In the LCC, as shown in Patent Document 1, for example, a process of extracting a hazardous pattern having a high possibility of causing a manufacture failure and a reduction in yield by using an EDA (Electronic Design Automation) tool, and a process of categorizing the hazardous pattern for each shape are performed. When extracting this hazardous pattern, a square detection area having a size determined in advance is normally set for each hazardous point centering on the coordinate values of the hazardous point. The EDA tool categorizes a hazardous pattern, based on the identity of each pattern shape included in the square detection area. A technical engineer or the like performs based on the result of its categorization, a risk degree determination for each category by visually confirming a representative pattern for each category.

In such a categorizing method, however, even when the size of the detection area is adjusted variously, the categorization result may be greatly deviated from the viewpoint of the technical engineer or the like. As a result, there is a fear that since the technical engineer or the like needs to suitably confirm even other hazardous patterns in addition to the representative pattern, a lot of time is required for the risk degree determination. Further, there is a fear that when the time is limited, the accuracy of the risk degree determination is degraded and a reduction in the yield at device manufacture occurs.

Embodiments to be described later have been made in view of such a situation. Other objects and novel features of the present invention will become apparent from the description of the present specification and the accompanying drawings.

In a method for inspecting a mask pattern according to one aspect of the present invention, when a detection point extracted in a lithography compliance check is categorized, a vertically long detection area and a horizontally long detection area centering on the detection point are provided for each detection point. The vertically long detection area is a rectangular detection area longer in a vertical direction than in a horizontal direction. The horizontally long detection area is a rectangular detection area longer in the horizontal direction than in the vertical direction. Further, in the mask pattern inspecting method, a plurality of detection points are categorized based on the identity of patterns included in the vertically long detection area and the identity of patterns included in the horizontally long detection area.

According to one aspect of the present invention, it is possible to shorten a time required for a risk degree determination in a lithography compliance check.

### BRIEF DESCRIPTION OF THE DRAWINGS

FIG. 1 is a flow diagram showing a schematic developing/manufacturing method of a semiconductor device;

FIG. 2 is a diagram, showing one example of the shape of each detection area set in FIG. 1 in a mask pattern inspecting method according to an embodiment 1 of the present invention;

FIG. 3 is a diagram showing one example of the shape of each detection area obtained by expanding FIG. 2 in the mask pattern inspecting method according to the embodiment 1 of the present invention;

FIG. 4 is a diagram describing one example of a categorizing method using the detection areas of FIG. 2;

FIG. 5 is a diagram describing one example of a categorizing method using the detection areas of FIG. 3;

FIG. 6A is a diagram describing benefits by using rectangular detection areas in the mask pattern inspecting method according to the embodiment 1 of the present invention;

FIG. 6B is a diagram following FIG. 6A;

FIG. 7A is a diagram showing a specific example of a situation in which the categorizing method shown in FIGS. 2 and 4 is applied;

FIG. 7B is a diagram following FIG. 7A;

FIG. 8A is a diagram snowing another specific example of a situation in which the categorizing method shown in FIGS. 2 and 4 is applied;

FIG. 8B is a diagram following FIG. 8A;

FIG. 9A is a diagram, showing the shape of the detection area set in FIG. 1 and a specific example of a situation in which the shape thereof is applied, in a mask pattern inspecting method according to an embodiment 2 of the present invention;

FIG. 9B is a diagram following FIG. 9A;

FIG. 10A is a diagram showing the shape of the detection area set in FIG. 1 and another specific example of a situation in which the shape thereof is applied, in the mask pattern inspecting method according to the embodiment 2 of the present invention;

FIG. 10B is a diagram following FIG. 10A;

FIG. 11A is a diagram describing one example of a specific system of realizing how to properly use each detection area in the mask pattern inspecting method according to the embodiment 2 of the present invention;

FIG. 11B is a diagram following FIG. 11A;

FIG. 12 is a diagram showing one example of the shape of a detection area set in FIG. 1 in a mask pattern inspecting method according to an embodiment 3 of the present invention;

FIG. 13A is a diagram showing a specific example of a situation in which the detection area of FIG. 12 is applied;

FIG. 13B is a diagram following FIG. 13A;

FIG. 14 is a diagram showing one example of the shape of a detection area obtained by expanding FIG. 12;

FIG. 15 is a diagram showing one example of the shape of a detection area set in FIG. 1 in a mask pattern inspecting method according to a comparative example of the present invention;

FIG. 16 is a diagram describing a relationship between the size of the detection area in FIG. 15 and a category number;

FIG. 17A is a diagram showing a specific example of a situation in which a problem occurs in the detection area of FIG. 15;

FIG. 17B is a diagram following FIG. 17A;

FIG. 18A is a diagram, showing another specific example of a situation in which a problem occurs in the detection area of FIG. 15; and

FIG. 18B is a diagram following FIG. 18A.

### DETAILED DESCRIPTION

The invention will be described by being divided into a plurality of sections or embodiments whenever circumstances require it for convenience in the following embodiments. However, unless otherwise specified in particular, they are not irrelevant to one another. One thereof has to do with modifications, details, supplementary explanations, etc, of some or all of the other. Also, when reference is made to the number of elements or the like (including the number of pieces, numerical values, quantity, range, etc.) in the following embodiments, the number thereof is not limited to a specific number and may be greater than or less than or equal to the specific number except for where otherwise specified in particular and definitely limited to the specific number in principle, etc.

It is further needless to say that in the following embodiments, components (also including element steps, etc.) employed therein are not always essential except for where otherwise specified in particular and considered to be definitely essential in principle, etc. Similarly, when reference is made to the shapes, positional relations and the like of the components or the like in the following embodiments, they will include ones substantially analogous or similar to their shapes or the like except for where otherwise specified in particular and considered not to be definitely so in principle, etc. This is similarly applied even to the above-described numerical values and range.

Preferred embodiments of the present invention will hereinafter be described in detail based on the accompanying drawings. Incidentally, the same reference numerals are respectively attached to the same members in principle in all the drawings for describing the embodiments, and a repeated description thereof will be omitted.

### Embodiment 1

«Developing/Manufacturing Method of Semiconductor Device»

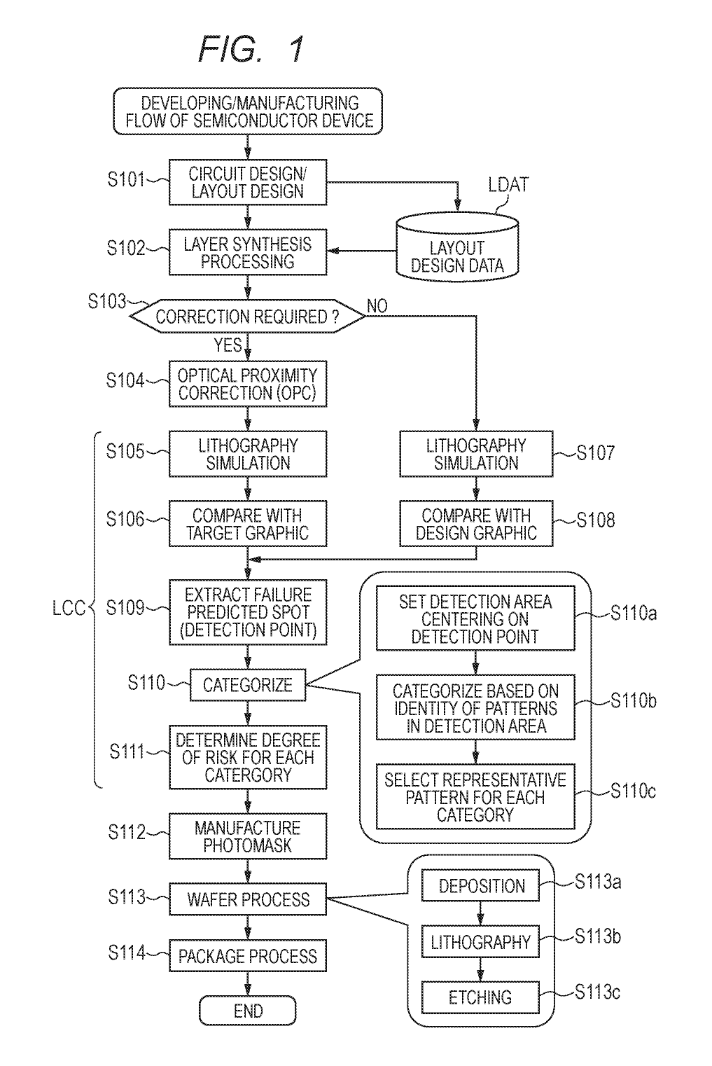

FIG. 1 is a flow diagram showing one example of a schematic developing/manufacturing method of a semiconductor device. In FIG. 1, circuit design of the semiconductor device and its layout design are first carried out so that layout design data LDAT of a plurality of layers are generated (Step S101). Following to it, a process of suitably synthesizing the respective layers having the layout design data LDAT is performed (Step S102). Then, a technical engineer or the like determines whether or not to need the correction (typically OPC) of a mask pattern according to a technology node, the position of a layer, the pattern attribute of each layer, etc, (Step S103), When the correction is required, the OPC is executed (Step S104), and a lithography compliance check (LCC) is executed with a mask pattern with the corresponding correction as an object. On the other hand, when the correction is unnecessary, the LCC is executed with a correction-absent mask pattern as an object.

In the LCC, a simulator being one of EDA tools performs a lithography simulation on the correction-present or -absent mask pattern and outputs a pattern to be inspected which, becomes its simulation result (Steps S105 and S107). As widely known, the EDA tool is realized by program processing using a computer system. The lithography simulation is mainly an optical simulation in which a change in shape by an exposure device is copied. The pattern to be inspected obtained as its result actually becomes a predicted pattern when transferred, to the semiconductor device. Incidentally, the lithography simulation is performed for each layer with a layer designated by the technical engineer or the like as an object.

Next, a pattern recognition tool being one of the EDA tools image-compares the pattern to be inspected output in Step S105 or S107 and a predetermined target pattern (Steps S106 and S108) to thereby extract, as a detection point (e.g., coordinate value), a spot where a lithography failure is predicted (Step S109). As the target pattern, for example, a target graphic is applied where the correction-present mask pattern is targeted. (Step S106), and a design, graphic is applied where the correction-absent mask pattern is targeted. (Step S108). The design graphic is one obtained by illustrating a pattern shape based on the layout design data LDAT. On the other hand, the target graphic is one obtained, by illustrating an ideal resist pattern shape after lithography, for example. This is one having such a property that when etching is done using this ideal shape, it becomes a design, graphic through a further change in shape.

Here, as specific examples of the lithography failure, there may be mentioned such as a resist size being less than the defined minimum dimension, the resist size being deviated from, a target dimension, a space from or overlap with an underlayer being insufficient (i.e., contact with, the underlayer becomes insufficient), etc. Such failure predicted spots frequently appear repeatedly in large numbers within one semiconductor chip. Therefore, the detection point in step S109 may be extracted in large numbers.

Thus, the pattern recognition tool categorizes a plurality of extracted detection points (Step S110). Specifically, the pattern recognition tool provides for each, detection point, a detection area centering on the detection point (Step S110a) and categorizes a plurality of detection points (in other words, a plurality of hazardous patterns) based on the identity of each pattern (called hazardous pattern in the specification) included in the detection area (Step S110b). At this time, the pattern recognition tool determines the identity of each pattern by using, as the hazardous pattern, for example, the target graphic or design graphic in Step S106 or S108, or in some cases, the post-correction mask pattern to be an input in Step S105, and assigns the hazardous patterns assumed to be same in pattern shape to the same category.

Subsequently, the pattern recognition tool selects a representative pattern from the plural hazardous patterns for each category (Step S110c). The representative pattern is defined to be, for example, a pattern in which the result obtained by the lithography simulation and image comparison (Steps S105 through S108) is a worst value (minimum dimension, maximum deviation value, minimum overlap amount or the like).

After the categorization is executed in this manner, the technical engineer or the like performs a risk degree determination for each category (Step S111). Specifically, the technical engineer or the like determines the degree of risk by, for example, sequential visual confirmation of the representative pattern for each category defined in Step S110, etc. and discriminates based on the result whether or not the fabrication of a mask is advanced. When it is determined that it is not possible to proceed with the mask manufacture, the technical engineer or the like suitably performs feedback work such as the correction of a mask pattern, etc. On the other hand, when it is determined that it is possible to proceed with the mask manufacture, the manufacture of a photomask is performed (Step S112).

Thereafter, a wafer process of forming each pattern in the semiconductor device using the mask fabricated through the LCC is performed (Step S113). A package process of performing packaging of the completed semiconductor device, etc. is performed (Step S114). In the wafer process, for example, a deposition process (Step S113a), a lithography process (Step S113b), and an etching process (Step S113c) are repeatedly executed.

In the deposition process, a predetermined film is formed over a semiconductor wafer by using various deposition devices representing a CVD (Chemical Vapor Deposition) device. In the lithography process, after a resist is applied onto the deposited film, the exposure device or the like patterns the resist using the fabricated photomask. In the etching process, an etching device etches the predetermined film through the patterned resist to pattern the predetermined film.

Here, when the risk degree determination is made to each individual hazardous pattern in Step Sill, time and effort required for such a determination become enormous. As side effects thereof, missing of a hazardous pattern truly high in risk degree, etc. may occur. Therefore, it becomes beneficial to perform categorization and select the representative pattern for each category in Step S110. It is however a prerequisite that in order to obtain the benefits, the categorization is appropriate.

### Categorizing Method (Comparative Example) and Its Problems

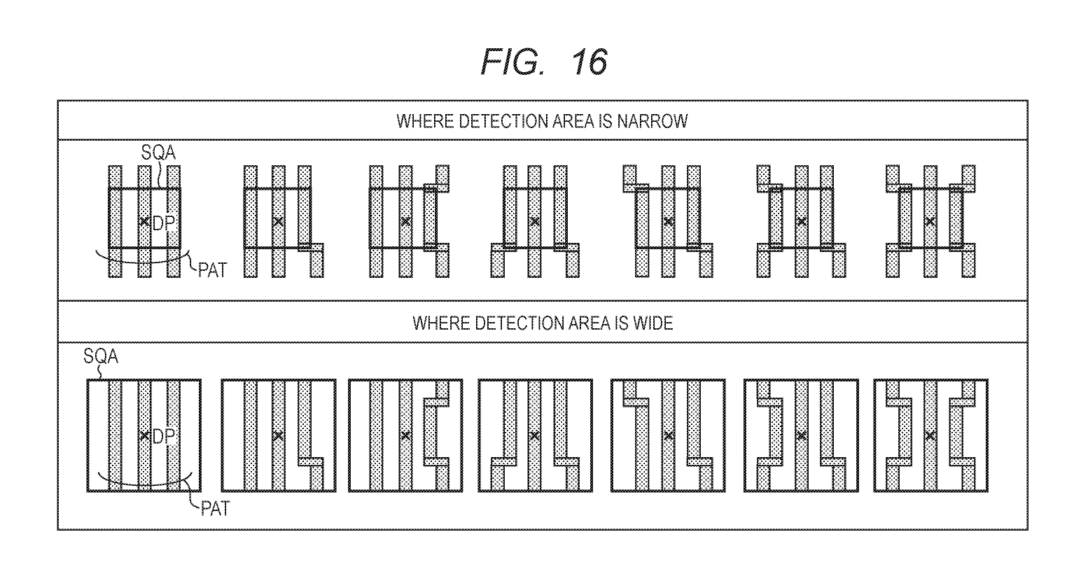

FIG. 15 is a diagram showing one example of the shape of a detection area set in FIG. 1 in a mask pattern inspecting method according to a comparative example of the present invention. FIG. 16 is a diagram describing a relationship between the size of the detection area in FIG. 15 and a category number. In the categorizing method showing the comparative example, in Step S110a of FIG. 1, a square detection area SQA centering on a detection point (e.g., spot where a failure such as thinning of a line is predicted) DP is provided as shown in FIG. 15. Patterns PAT included in the detection area SQA become hazardous patterns.

The number of categories obtained in Step S110b depends on the size of the detection area SQA. Specifically, as the detection area SQA becomes narrow, the number of categories is reduced, but the number of hazardous patterns in one category is increased. As the detection area SQA becomes wide, the number of categories is increased, but the number of hazardous patterns in one category is reduced. In the example of FIG. 16, when the detection area SQA is narrow, the number of categories becomes 1, and seven patterns (hazardous patterns) PAT are included therein. Further, when the result of simulation of the detection point DP (Steps S105 to S108) is a worst value (e.g., such as the dimension being the thinnest) in the leftmost pattern PAT, the leftmost pattern PAT becomes a representative pattern of the corresponding category.

On the other hand, when the detection area SQA is wide, the number of categories becomes seven and the number of patterns (hazardous patterns) PAT in each category becomes one. Thus, the quality and efficiency of categorizing depend on the shape of the detection area SQA. The appropriate size of the detection area SQA is three to four times as large as an “exposure wavelength/opening number” being a size experientially assumed to be sufficiently small in effect of each distant pattern (optical proximity effect), or three to four times as large as the minimum pitch being the minimum size capable of taking in the effect of a second, adjacent pattern.

In the categorizing method showing the comparative example, however, even, when the size of the detection area SQA is made appropriate, the result of categorization maybe greatly deviated from the viewpoint of the technical engineer or the like. As a result, since the technical engineer or the like needs to suitably confirm even other hazardous patterns in addition to the representative pattern in. Step S111 of FIG. 1, there is a fear that a lot of time will be required for the risk degree determination. Further, when the time is limited, the accuracy of the risk degree determination is degraded, and there is a fear that a reduction in yield at device manufacture will be caused.

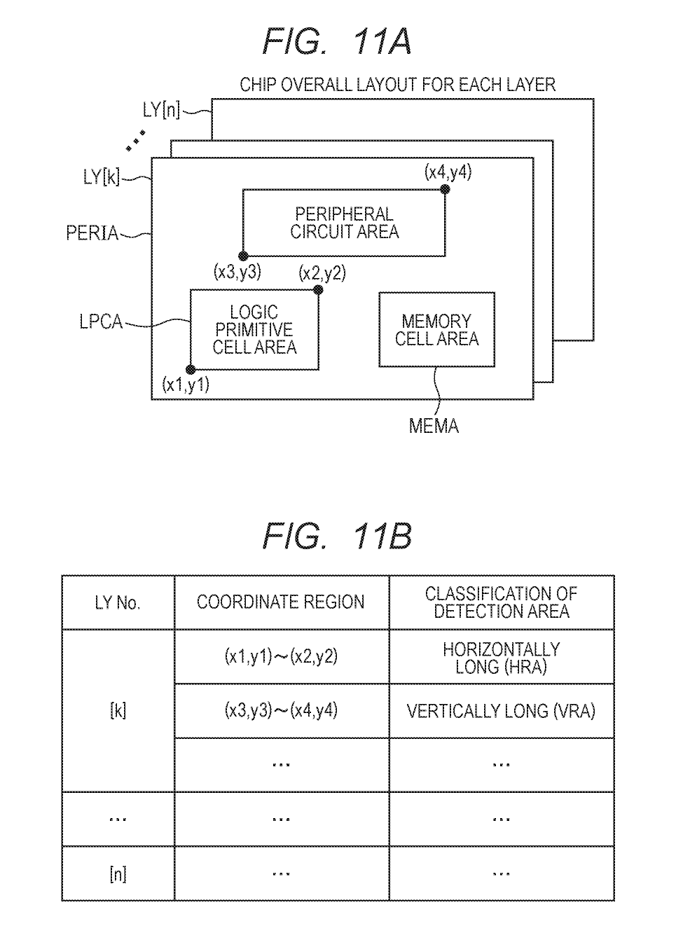

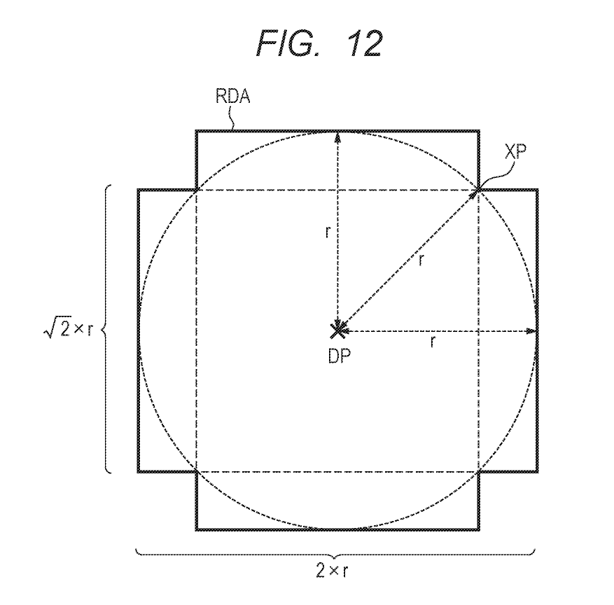

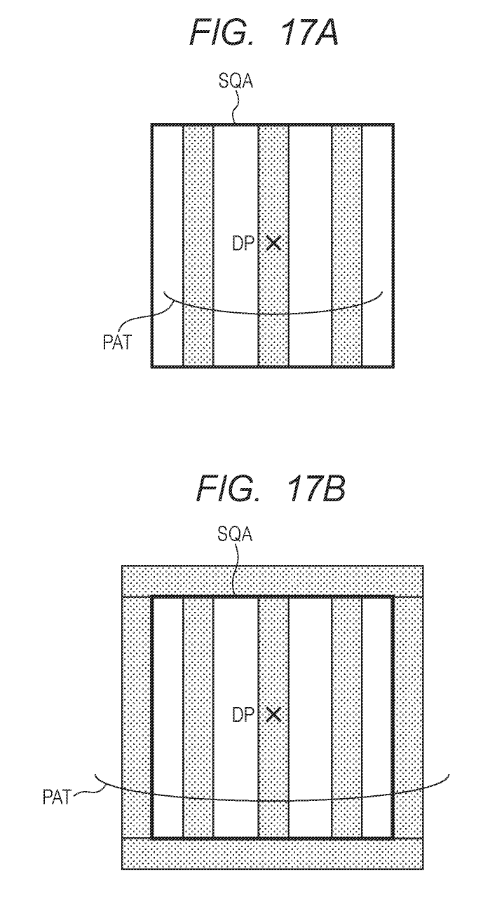

As a specific case in which the categorizing method showing the comparative example becomes a problem, first, there may be mentioned a case in which the categorization is insufficient. In this case, a plurality of patterns preferable to be another category are classified into the same category, FIGS. 17A and 17B are respectively diagrams showing a specific example of a situation in which a problem occurs in the detection area of FIG. 15. For example, the outside of the detection area SQA centering on the detection point DP is blank in FIG. 11A, whereas in FIG. 17B, the outside thereof is surrounded by wiring patterns.

Since FIGS. 17A and 17B are completely opposite to each other in terms of the effect (i.e., optical proximity effect) of each distant pattern, they are desirably classified into different categories in the viewpoint of the technical engineer or the like, but classified into the same category. Since it is necessary to re-determine a hazardous pattern group determined to be the same category once for the purpose of avoiding missing of verification, the man-hour of the risk degree determination is increased as a result. Incidentally, though they can be classified into different categories when the size of the detection area SQA is made wide, there is a fear that a case in which categorization to be described next is excessive will frequently occur.

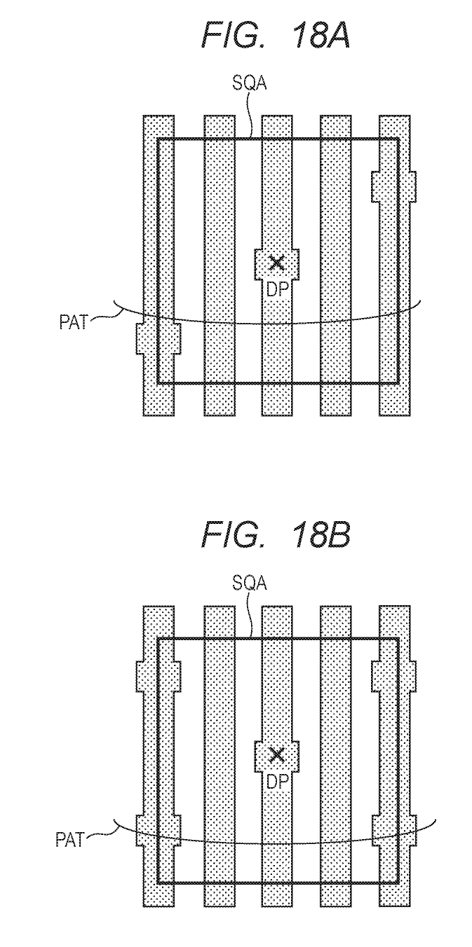

Secondly, there may be mentioned a case in which the categorization is excessive. In this case, a plurality of hazardous patterns desirable to be under the same category are classified into another category. FIGS. 18A and 18B are respectively diagrams showing another specific example of a situation in which a problem occurs in the detection area of FIG. 15. Patterns (hazardous patterns) PAT shown in FIGS. 18A and 18B have locally thick wiring spots because of execution of contact between layers, etc., for example.

As the wiring spots, there are three in FIG. 18A and five in FIG. 18B, Since FIGS. 18A and 18B are substantially equal to each other in terms of the effect (i.e., optical proximity effect) of each distant pattern, they are desirably classified into the same category in the viewpoint of the technical engineer or the like, but classified into another category. Therefore, the number of categories requiring the risk degree determination is increased, and the man-hour of the risk degree determination is increased as a result. Incidentally, though they can be classified into the same category when the detection area SQA is made narrow, there is a fear that a case in which the above-described categorization is insufficient will frequently occur.

Such a case is essentially considered to occur due to the following two problems. The first problem, resides in that how to take the detection, area SQA is uniform and. the graphic features of each pattern PAT are not taken into consideration. The second problem resides in that since the detection area. SQA is a single square, the distance between the detection point DP and the vertex of the detection area SQA as seen in an oblique direction becomes excessively long (becomes √2 times) as compared with the vertical or horizontal distance between the detection point DP and each side of the detection, area SQA, and the optical proximity effect determined by the distance from, the detection point DP is not taken into consideration. That is, the excessive categorization is made in the oblique direction.

### Categorizing Method (Embodiment 1)

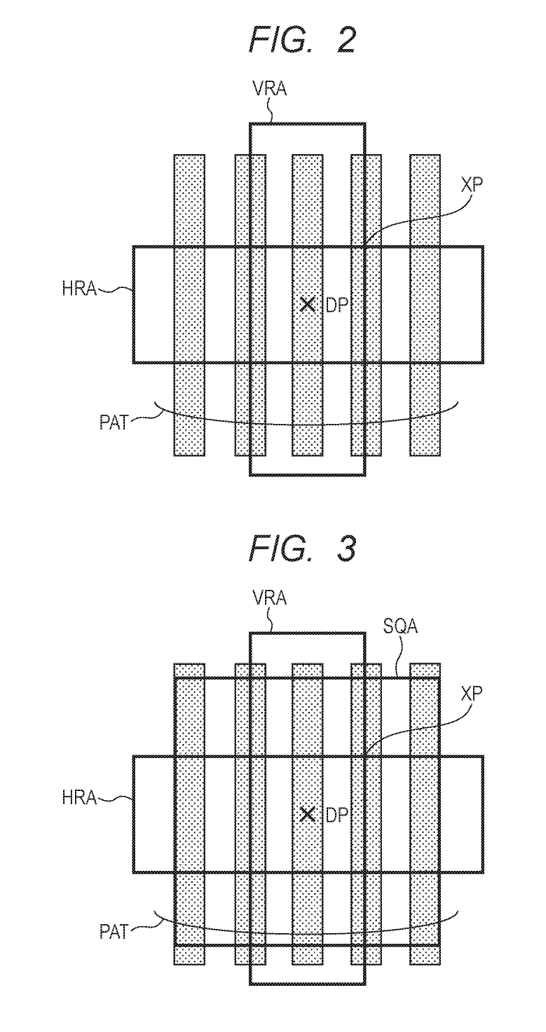

FIG. 2 is a diagram showing one example of the shape of each detection area set in FIG. 1 in a mask pattern inspecting method according to an embodiment 1 of the present invention. In Step S110a of FIG. 1, rectangular detection areas each centering on a detection point DP are provided unlike the case of FIG. 15 in the embodiment 1 (embodiments to be described later are also similar). The rectangular detection area is comprised of sides parallel to the principle-based direction of drawing of a mask pattern. That is, the principle-based direction of drawing of the mask pattern corresponds to vertical and horizontal directions. The rectangular detection area is comprised of the sides extending in the vertical and horizontal directions.

In the example of FIG. 2, there are provided as the rectangular detection areas, a vertically long detection area VRA longer in the vertical direction than in the horizontal direction, and a horizontally long detection area HRA longer in the horizontal direction than in the vertical direction. Although the sizes of the vertically long detection area VRA and the horizontally long detection area HRA are not necessarily limited, the long side of each of the detection areas is five to ten times as large as an “exposure wavelength/opening number” or a minimum pitch, and the short side thereof is two to three times the “exposure wavelength/opening number” or the minimum pitch.

FIG. 3 is a diagram showing one example of the shape of each detection area obtained by expanding FIG. 2 in the mask pattern inspecting method according to the embodiment 1 of the present invention. In the example of FIG. 3, a square detection area SQA centering on a detection point DP is provided for each detection point DP as with FIG. 15 in addition to a vertically long detection area VRA and a horizontally long detection area HRA each formed as a rectangular detection area.

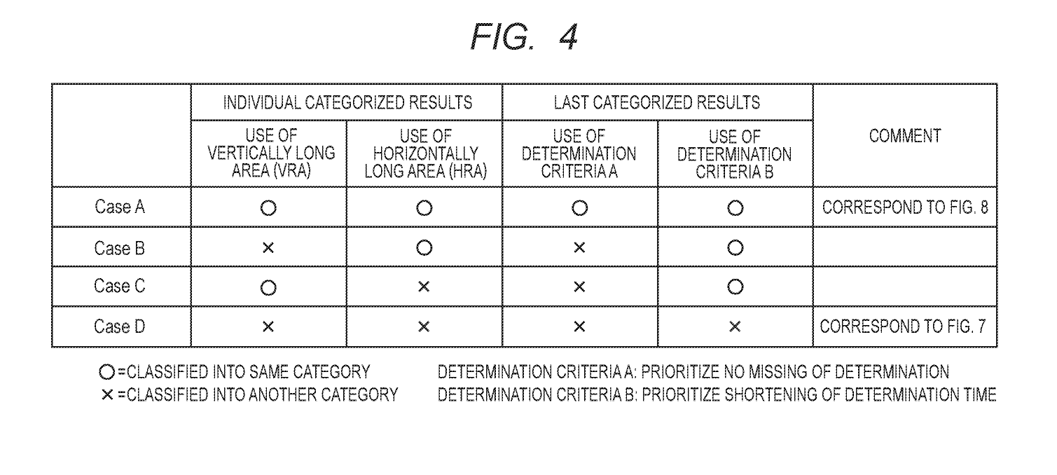

FIG. 4 is a diagram describing one example of a categorizing method using the detection areas of FIG. 2. In Step S110b of FIG. 1, a pattern recognition tool executes individual categorization using the vertically long detection area VRA and the horizontally long detection area HR& individually. That is, the pattern recognition tool categorizes a plurality of detection points DP (in other words, a plurality of hazardous patterns), based on the identity of patterns PAT included in the vertically long detection area VRA, and categorizes a plurality of detection points DP, based on the identity of patterns PAT included in the horizontally long detection area HRA.

As a result, as shown in FIG. 4, four types of cases from a case A to a case D are generated according to the two individual categorized results, “o” in the FIG. indicates that two arbitrary hazardous patterns are classified into the same category, “x” in the figure indicates that they are classified into another category. The pattern recognition tool eventually categorizes a plurality of detection points DP, based on the two individual categorized results (i.e., Cases A to D).

When performing the last categorization, the pattern recognition tool is capable of using, for example, two determination criteria (determination criteria A and B). The determination criteria A is one which prioritizes preventing of determination missing done by the technical engineer or the like. When the determination criteria A is used, two arbitrary hazardous patterns are classified into another category even in the last categorized results when classified into another category at one or more of the two individual categorized results.

On the other hand, the determination criteria B is one which prioritizes shortening of a determination time by the technical engineer or the like. When the determination criteria B is used, two arbitrary hazardous patterns are classified into the same category in last categorized results unless they are determined to be classified into another category in all of the two individual categorized results. Incidentally, even when both of the determination criteria A and the determination criteria B are used, the pattern recognition tool classifies two arbitrary hazardous patterns classified into the same category at both of the two individual categorized results into the same category (Case A). Further, the pattern recognition tool classifies two arbitrary hazardous patterns classified into another category at both of the two individual categorized results into another category (Case D).

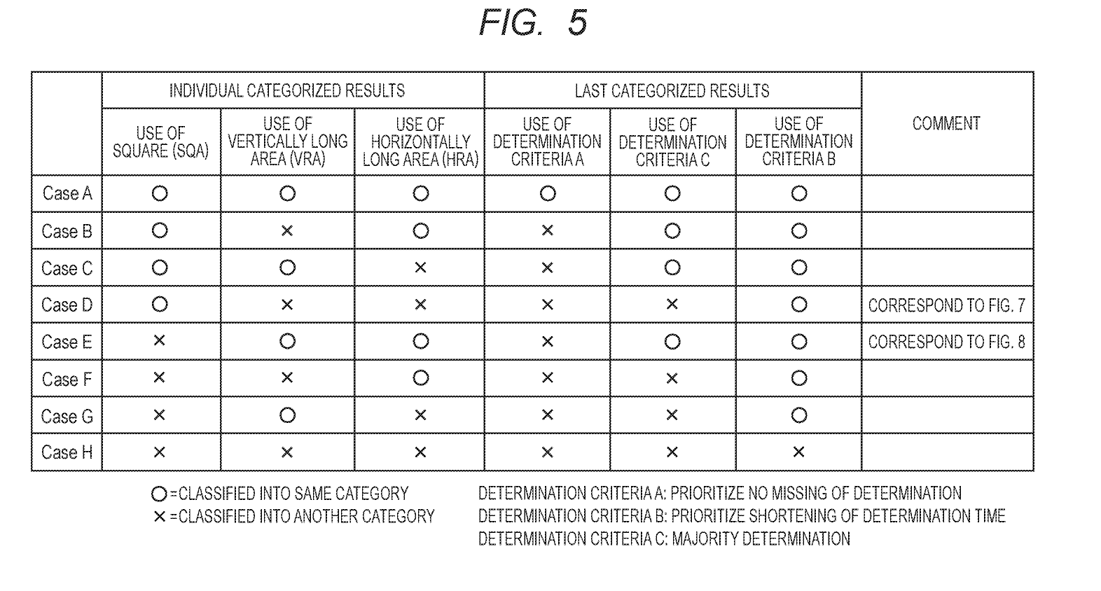

FIG. 5 is a diagram, describing one example of a categorizing method using the detection areas of FIG. 3. In Step S110b of FIG. 1, the pattern recognition tool executes individual categorization, by individually using the vertically long detection area VRA, the horizontally long detection area HRA, and the square detection area SQA. That is, the pattern recognition tool categorizes a plurality of detection points DP, based on the identity of each pattern PAT included in the square detection, area SQA in addition to the processing described in FIG. 4.

As a result, eight types of cases from a Case A to a Case H are generated, according to the three individual categorized results as shown, in FIG. 5. The pattern recognition tool eventually categorizes a plurality of detection points DP, based on the three individual categorized results (i.e., Case A to Case H). At this time, the pattern recognition tool is capable of using a determination criteria C in addition to the two determination criteria (determination criteria A and determination criteria B) described in FIG. 4. The majority determination of the three individual categorized results is used in the determination criteria C.

When the determination criteria C is used, the pattern recognition tool classifies two arbitrary hazardous patterns classified into the same category at two or more of the three individual categorized results into the same category even in the last categorized results. Further, the pattern recognition tool classifies two arbitrary hazardous patterns classified into another category at two or more of the three individual categorized results into another category even in the last categorized results.

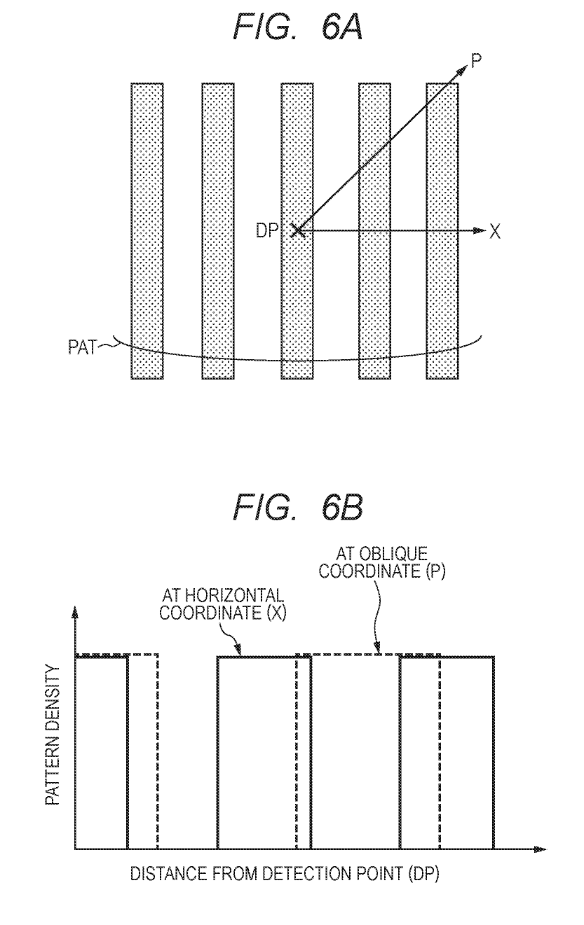

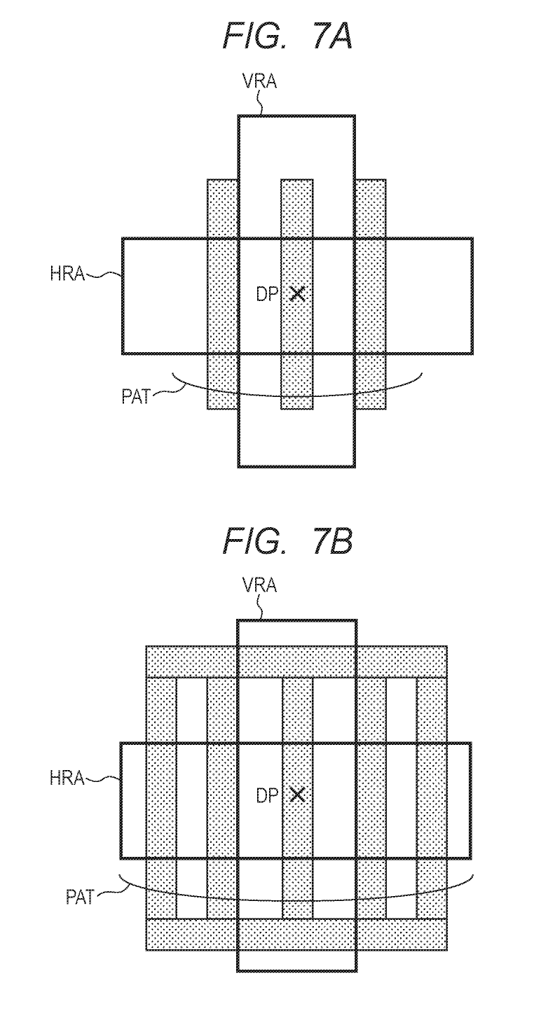

This will be described below by a specific example. FIGS. 7A and 7B are respectively diagrams showing a specific example of a situation in which the categorizing method in FIGS. 2 and 4 is applied. Patterns PAT shown in FIGS. 7A and 7B are respectively the same as those shown in FIGS. 17A and 17B. Three wiring patterns are provided within a horizontally long detection area HRA in FIG. 7A, and five wiring patterns are provided therewithin in FIG. 7B. Therefore, hazardous patterns in FIG. 7A and hazardous patterns in FIG. 7B are respectively classified into another category.

Further, an I-shaped wiring pattern is provided within a vertically long detection area VRA in FIG. 7A, and an H-shaped wiring pattern is provided therewithin in FIG. 7B. Therefore, the hazardous patterns of FIG. 7A and the hazardous patterns of FIG. 7B are respectively classified into another category. As a result, as shown in the Case D of FIG. 4, FIGS. 7A and 7B are classified into another category even in the last categorization. Since FIGS. 7A and 7B are actually completely opposite in terms of the effect (i.e., optical proximity effect) of each distant pattern, the classification into another category matches with the viewpoint of the technical engineer or the like.

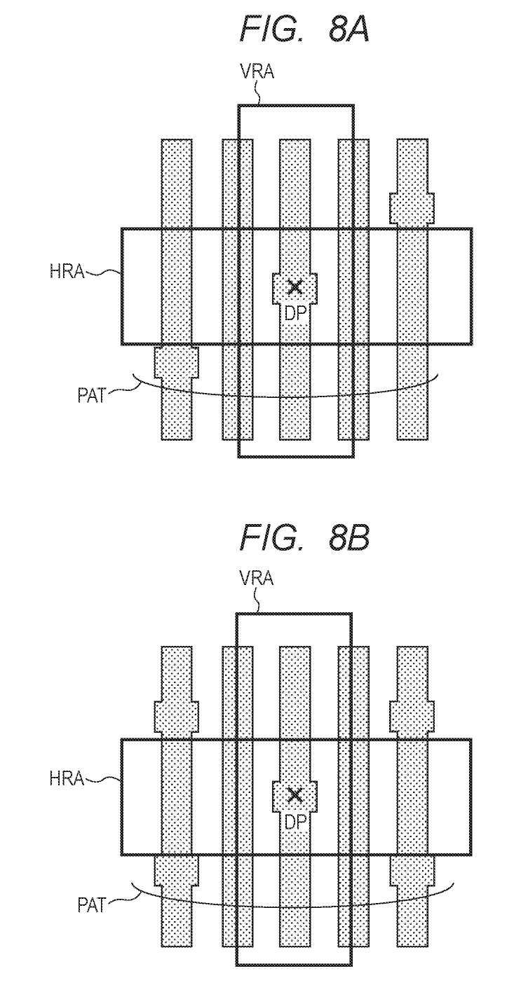

FIGS. 8A and 8B are respectively diagrams showing another specific example of a situation in which the categorizing method in FIGS. 2 and 4 is applied. Patterns PAT shown in FIGS. 8A and 8B are respectively the same as those shown in FIGS. 18A and 18B, One locally-thick wiring spot is shown within a horizontally long detection area HRA in both of FIGS. 18A and 18B. Therefore, hazardous patterns in FIG. 8A and hazardous patterns in FIG. 8B are classified into the same category.

Further, one locally-thick wiring spot is shown even within a vertically long detection area VRA in both of FIGS. 18A and 18B. Therefore, the hazardous patterns in FIG. 8A and the hazardous patterns in FIG. 8B are respectively classified into the same category. As a result, as shown in the Case A of FIG. 4, FIGS. 8A and 8B are classified into the same category even in the last categorization. Since FIGS. 8A and 8B are actually substantially equal to each other in terms of the effect (i.e., optical proximity effect) of each distant pattern, the classification into the same category matches with the viewpoint of the technical engineer or the like.

As described above, the use of the categorizing method (i.e., method by vertically long detection area VRA and horizontally long detection area HRA) in FIGS. 2 and 4 makes it possible to perform the categorization matching with the viewpoint of the technical engineer or the like unlike the use of the categorizing method (i.e., method by square detection area SQA) in FIG. 15. On the other hand, when the categorizing method (i.e., method by vertically long detection area VRA, horizontally long detection area HRA., and square detection area SQA) in FIGS. 3 and 5 is used, it is possible to perform categorization which matches with the viewpoint of the technical engineer or the like by using the determination criteria C of FIG. 5.

Specifically, FIGS. 7A and 7B can be classified into another category as shown in the Case D by using the determination criteria C of FIG. 5. FIGS. 8A and 8B can be classified into the same category as shown in the Case E by using the same. In other words, those classified into the same category can be classified into another category in the square detection area SQA as shown in the Case D because the vertically long and horizontally long results are both intended for another category. Further, as shown in the Case E, those classified into another category can be classified into the same category in the square detection area SQA because the vertically long and horizontally long results are both intended for the same category.

Incidentally, as understood from the fact that FIGS. 8A and 8B are classified into another category, the determination criteria A of FIG. 5 is estimated to include many cases in which the categorization is excessive. As understood from the fact that FIGS. 7A and 7B are classified into the same category, the determination criteria B of FIG. 5 is estimated to include many cases in which the categorization is insufficient. Thus, when the categorizing method shown in FIGS. 3 and 5 is used, the categorizing method is not necessarily limited to it, but the determination criteria C is preferably used.

Here, the categorizing method in FIGS. 2 and 4, and the categorizing method in FIGS. 3 and 5 are compared. First, when the categorizing method in FIGS. 2 and 4 is used, no problem occurs in particular where the two individual categorized results are matched with each other as in the Cases A and D in FIG. 4. When, however, the two individual categorized results are not matched as in the Cases B and C, there is no objective guideline for fixing the last categorized results. As a result, such Cases are cases different from FIGS. 7 and 8, and there is a fear that it will become difficult to obtain the categorized results coincident with the viewpoint of the technical engineer or the like.

On the other hand, in the categorizing method in FIGS. 3 and 5, the last categorized results can be determined by use of the determination criteria C of FIG. 5 with the individual categorized results based on the square detection area SQA as guidelines where the two individual categorized results based on the vertically long detection area VRA and the horizontally long detection area HRA are not matched as in the Cases B, C, F, and G. As a result, it is considered that it becomes easy to obtain the categorized results coincident with the viewpoint of the technical engineer or the like as compared with the case where the categorizing method in FIGS. 2 and 4 is used.

### Main Effects of Embodiment 1

As described above, the categorization (i.e., selection of representative pattern) is made appropriate by using the vertically long detection area VRA and the horizontally long detection area HRA upon performing the categorization in the lithography compliance check (LCC), thus making it possible to shorten the time required for the risk degree determination. As a result, it is possible to improve the accuracy of the risk degree determination within a limited time. By extension, it is possible to achieve an improvement in yield at device manufacture, etc. The benefits obtained by using such rectangular detection areas (VRA and HRA) will hereinafter be described in more detail.

FIGS. 6A and 6B are respectively diagrams describing the benefits by using the rectangular detection areas in the mask pattern inspecting method according to the embodiment 1 of the present invention. The embodiment 1 focuses attention on a general feature that patterns of a semiconductor device are mainly drawn in two directions of a horizontal direction and a vertical direction. As a result of drawing of the patterns in the two horizontal and vertical directions, the cycle of a change in pattern density becomes relatively gentle in an oblique direction while becoming dense in the two horizontal and vertical directions. FIGS. 6A and 6B are diagrams typically showing it. The denseness of the change in pattern density is synonymous with the diversity of the pattern. Therefore, it is essentially desirable to determine the identity of each pattern while placing an emphasis on information in the horizontal and vertical directions rather than information in the oblique direction.

In the embodiment 1, the rectangular detection areas (VRA and HRA) are used from such a viewpoint. That is, when such a square detection area SQA as shown in FIG. 15 is used, the information in the oblique direction is placed under emphasis, but when the rectangular detection areas (VRA, HRA) are used, the information in the horizontal and vertical directions can be placed under emphasis. As a result, it is possible to more appropriately categorize diverse patterns.

Further, the use of both the vertically long detection area VRA and the horizontally long detection area HRA becomes beneficial in terms of the optical proximity effect. As described above, the optical proximity effect is determined depending on the distance from the detection point. Now assume where the two detection areas (VRA and HRA) in FIG. 2 are respectively defined to be a rectangle whose ratio (short side/long side)(= 2/10) becomes maximum. In this case, the distance (assumed to be 2√2, for example) between the detection point DP and an intersection point XP of boundaries of the two detection areas (VRA and HRA) becomes 0.28 times (=2√2/10) the distance (being 10) from the detection point DP to the short side of the rectangle. Further, assume where the two detection areas (VRA and HRA) in FIG. 2 are respectively defined to be a rectangle whose ratio (short side/long side) becomes minimum (=3/5). In this case, similarly, the distance between the detection point DP and the intersection point XP becomes 0.84 times (=3√2/5) the distance from the detection point DP to the snort side.

Thus, when both of the vertically long detection area VRA and the horizontally long detection area HRA are combined to determine the identity of each pattern, the amount of information in the oblique direction becomes 0.28 to 0.84 times the amount of information in the horizontal and vertical directions. This magnification may be one times as an ideal value when only the optical proximity effect is simply taken into consideration. Since, however, the information in the horizontal and vertical directions is more increased in the level of importance than the information in the oblique direction in light of the graphic features described in FIGS. 6A and 6B, it can be said as being preferably appropriate that the magnification is smaller than one times.

### Embodiment 2

### Categorizing Method (Embodiment 2)

In the above-described categorizing method according to the embodiment 1, both of the vertically long detection area VRA and the horizontally long detection area HRA are provided for each detection point DP. On the other hand, in a categorizing method according to an embodiment 2, either one of a vertically long detection area VRA and a horizontally long detection area HRA is provided for each detection point DP, based on a circuitry feature of a circuit disposed at the detection point DP. Points of essential difference from the case of the embodiment 1 reside in that the feature of the circuit is also taken into consideration in addition to the graphic feature of each pattern and the optical proximity effect. Incidentally, the size of each of the detection areas (VRA and HRA) is similar to that in the case of the embodiment 1. The present embodiment will be described below using a specific example.

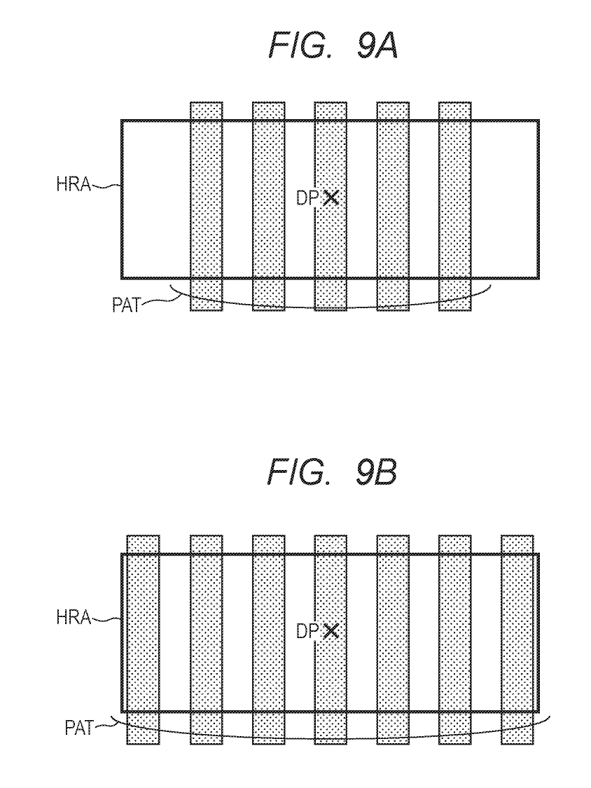

FIGS. 9A and 9B are respectively diagrams showing the shape of the detection area set in FIG. 1 and a specific example of a situation in which the shape thereof is applied, in a mask pattern inspecting method according to the embodiment 2 of the present invention. Typical patterns PAT of a logic primitive cell are shown in FIGS. 9A and 9B. The patterns PAT correspond to, for example, a gate wiring pattern of a gate layer, etc. A graphic feature of the logic primitive cell is limited in cell height, and a circuitry feature thereof is sensitive to a fluctuation in line width. The fluctuation in line width is brought by a coarse/fine difference in a direction (horizontal direction) orthogonal to the extending direction (vertical direction herein) of each wiring pattern, and a difference in the number between the wiring patterns.

In such a case, as shown in FIGS. 9A and 9B, categorization taking the dense-coarse difference and the difference in the number into consideration is made possible by providing a horizontally long detection area HRA longer in the horizontal direction than in the vertical direction. In FIG. 9A, five wiring patterns are provided as patterns (hazardous patterns) PAT in the horizontally long detection area HRA. In FIG. 9B, seven wiring patterns are provided as patterns PAT in the horizontally long detection area HRA. As a result, FIGS. 9A and 9B can respectively be classified into another category, thus making it possible to make the categorization appropriate (such as making an improvement in the accuracy of a risk degree determination, etc.)

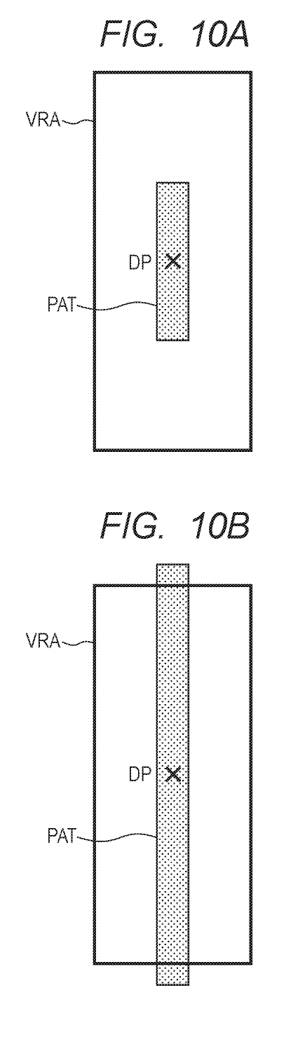

FIGS. 10A and 10B are respectively diagrams showing the shape of the detection area set in FIG. 1 and another specific example of a situation in which the shape thereof is applied, in the mask pattern inspecting method according to the embodiment 2 of the present invention. A typical patterns PAT of a peripheral circuit is shown in each of FIGS. 10A and 10B. The patterns PAT correspond to, for example, a metal wiring pattern of a metal wiring layer, etc. A circuitry feature of the peripheral circuit resides in that the diversity of the patterns PAT is high while the circuitry feature is not sensitive so much to a fluctuation in line width. In particular, the length of the wiring pattern and the shape of its end (whether the wiring pattern being connected to another wiring pattern) directly lead to the degree of risk of resist pattern falling in a lithography process.

In such a case, since the extending direction of the wiring pattern corresponds to the vertical direction as shown in each of FIGS. 10A and 10B, categorization which considers the degree of risk of the resist pattern falling is made possible by providing a vertically long detection area VRA longer in the vertical direction than in the horizontal direction. In FIG. 10A, a short wiring pattern is provided as a pattern (hazardous pattern) PAT in the vertically long detection area VRA. In FIG. 10B, a long wiring pattern is provided as a pattern PAT in the vertically long detection area VRA. As a result, FIGS. 10A and 10B can respectively be classified into another category, thus making it possible to make the categorization appropriate (such as making an improvement in the accuracy of a risk degree determination, etc.)

In order to apply such a system, for example, the technical engineer or the like determines in advance, a correspondence relation between layout information of each circuit block and classification information (i.e., vertically long detection area VRA or horizontally long detection area HRA) of a detection area applied for each circuit block. FIGS. 11A and 11B are respectively diagrams describing one example of a specific system of realizing how to properly use a detection area in the mask pattern inspecting method according to the embodiment 2 of the present invention.

As shown in FIG. 11A, the technical engineer or the like is capable of obtaining layout information of each circuit block for each layer, based on the layout design data (i.e., overall layout diagram, of semiconductor chip) LDAT of FIG. 1, etc, for example. In the example of FIG. 11A, in a layer LY [k], a region of coordinates (x1, y1) to (x2, y2) becomes a logic primitive cell area LPGA, and a region of coordinates (x3, y3) to (x4, y4) becomes a peripheral circuit area PERIA. Various circuit blocks are disposed like a memory cell area MEMA, etc. in the layer LY [k] even in addition to the above.

The technical engineer or the like is capable of determining such a correspondence relation as shown, in FIG. 11B, based, on the layout information of each, circuit block shown in FIG. 11A, a circuitry feature of each circuit block, and a preferential wiring direction (vertical direction or horizontal direction) defined for each layer. In the example of FIG. 11B, the horizontally long detection area HRA is made to correspond to a coordinate region (x1, y1) to (x2, y2) (i.e., logic primitive cell area LPGA) of a layer LY [k]. The vertically long detection area VRA is made to correspond to a coordinate region (x3, y3) to (x4, y4) (i.e., peripheral circuit area PERIA) of the layer LY [k].

The technical engineer or the like registers such a correspondence relation as shown in FIG. 11B, for example, in a pattern recognition tool. The pattern recognition tool determines, based on the correspondence relation, whether a detection point (e.g., coordinate value) DP is included in any coordinate region of each circuit block, thereby making it possible to categorize a plurality of detection points while properly using the vertically long detection area VRA and the horizontally long detection area HRA for each detection point.

Upon this categorization, the pattern recognition tool performs categorization with, for example, a pattern to which the vertically long detection area VRA is applied, as an object. Aside from this, the pattern recognition tool performs categorization with a pattern to which the horizontally long detection area HRA is applied, as an object. Alternatively, the pattern recognition tool may classify different circuit blocks into other upper categories in advance and then categorize hazardous patterns included in each circuit block as a lower category of the respective upper categories.

### Main Effects of Embodiment 2

As described above, the categorization (i.e., selection of representative pattern) is made appropriate by suitably using the vertically long detection area VRA and the horizontally long detection area HRA according to the circuitry feature upon performing the categorization in the lithography compliance check (LCC), thereby making it possible to shorten the time required for the risk degree determination. As a result, it is possible to improve the accuracy of the risk degree determination within a limited time. By extension, it is possible to achieve an improvement in yield at device manufacture, etc.

### Embodiment 3

### Categorizing Method (Embodiment 3)

FIG. 12 is a diagram showing one example of the shape of a detection area set in FIG. 1 in a mask pattern inspecting method according to an embodiment 3 of the present invention. In the embodiment 3, the detection area has a shape obtained by superposing a plurality of rectangles centering on a detection point DP and is comprised of stepwise sides extending in horizontal and vertical directions. Incidentally, the rectangle means a quadrangle whose four corners are all at 90°.

As one example of such a detection area, a detection area RDA of FIG. 12 has a shape obtained by superposing a vertically long rectangle longer in the vertical direction than in the horizontal direction, and a horizontally long rectangle longer in the horizontal direction than in the vertical direction. The sizes of the vertically long rectangle and the horizontally long rectangle are both three to four times an “exposure wavelength/opening number” or a minimum pitch in terms of their long sides, and two to three times an “exposure wavelength/opening number” or a minimum pitch in terms of their short sides. A size ratio between the long and short sides is √2.

The feature of the embodiment 3 resides in that the optical proximity effect is more emphasized. Therefore, as shown in FIG. 12, the vertically long rectangle and the horizontally long rectangle are both configured such that the size ratio between the long and short sides becomes √2. At this time, the distance (r) between the detection point DP and an intersect ion point XP of the boundaries of the vertically long rectangle and the horizontally long rectangle becomes 1 times the distance (r) between the detection point DP and each of the horizontal and vertical sides. This becomes an ideal ratio in terms of the optical proximity effect.

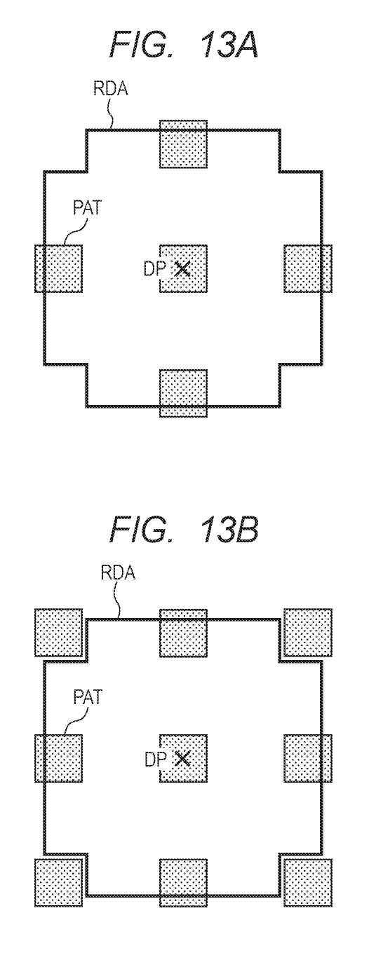

Here, the above-described embodiment 1 has described that the oblique-direction distance (amount of information) relative to the horizontal and vertical distances (in other words, amount of information) maybe smaller than 1 times in light of the graphic feature of the pattern (e.g., wiring pattern). There is however a case where the distance is preferably 1 times depending on the patterns as shown in FIGS. 13A and 13B. FIGS. 13A and 13B are respectively diagrams showing a specific example of a situation in which the detection area of FIG. 12 is applied.

A contact hole pattern group having large contribution to the optical proximity effect is shown in each of FIGS. 13A and 13B. Each individual contact hole pattern is assumed to be an independent point light source. In FIG. 13A, five contact hole patterns are provided within a square. In FIG. 13B, nine contact hole patterns are provided within the square. When such a square detection area SQA as shown in FIG. 15 is used, excessive categorization is made in an oblique direction, so that FIGS. 13A and 13B are classified into another category. On the other hand, when the detection area RCA of FIG. 12 is used, the categorization in the oblique direction is made appropriate, so that FIGS. 13A and 13B are both classified into the same category because the number of the contact hole patterns in the detection area RCA is five.

A point of difference between FIGS. 13A and 13B resides in the presence or absence of patterns disposed in the oblique direction centering on the detection point DP. Actually, in the case of the patterns disposed in the oblique direction as compared with the patterns disposed in the horizontal and vertical directions, a contribution to the optical proximity effect becomes relatively minor from the relationship of the distance from the detection point DP. Therefore, the classification of FIGS. 13A and 13B into the same category matches with the viewpoint of the technical engineer or the like. Incidentally, when the detection area RDA is applied to the contact hole pattern group, an application destination of the detection area RDA may be determined in advance in a manner similar to the above-described case in FIGS. 11A and 11B.

Here, the shape of the detection area RDA shown in FIG. 12 takes a shape which focuses attention on the feature that “the direction of drawing of each pattern is horizontal and vertical directions in principle regardless of a wiring pattern, a hole pattern, etc. That is, only in the viewpoint that the distance from the detection point DP is set to 1 times, the shape of the detection area may be a regular dodecagon, a regular icositetragon, etc., or may be a circle ultimately. When, however, the detection area including such oblique lines and curves is used, the identity of each pattern at the boundary part of the detection area becomes difficult to be obtained in an unnecessary manner with mismatching with the drawing direction of the pattern, and hence the number of categories is in danger of becoming huge.

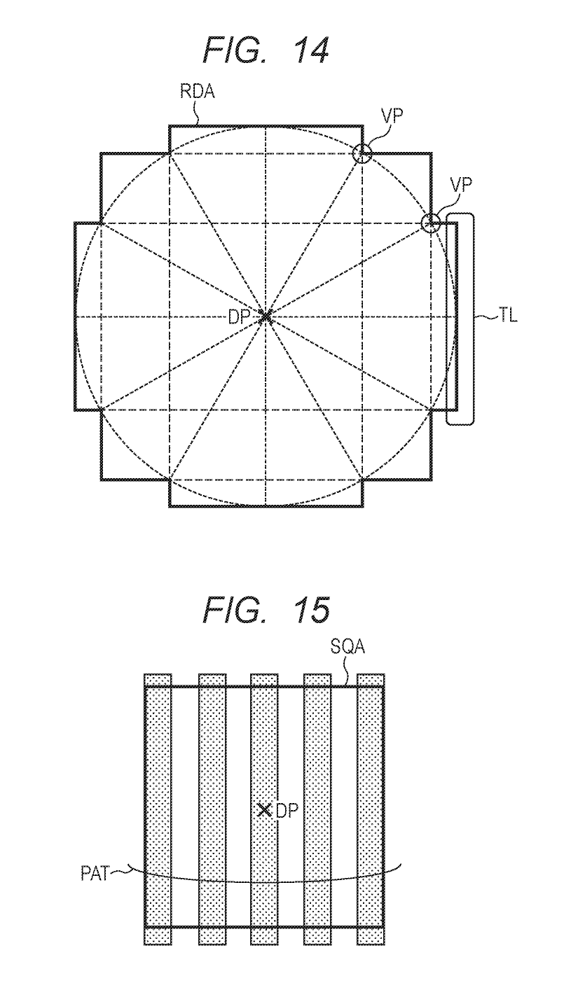

Thus, in the embodiment 3, the shape of such a detection area as to be close to the circle by combining a plurality of rectangles is used. From this point of view, it is also possible to make the detection area RDA closer to the circle by increasing the number of the rectangles to be combined more than the case of FIG. 12 as shown in FIG. 14, for example. FIG. 14 is a diagram showing one example of the shape of a detection area obtained by expanding FIG. 12, The shape of the detection area RDA shown in FIG. 14 (FIG. 12 being also similar) has the following features. As the first feature, the vertices VP of corners protruded toward the detection point DP side, each of which is formed with the stepwise side of the detection area RDA, are disposed together on the same circle centering on the detection point DP. As the second feature, some TL of the stepwise sides become the tangential lines of the same circle.

### Main Effects of Embodiment 3

As described above, the categorization (i.e., selection of representative pattern) is made appropriate by using the polygonal detection area RDA close to the circle upon performing the categorization in the lithography compliance check (LCC), and the time required for the risk degree determination can be shortened. As a result, it is possible to improve the accuracy of the risk degree determination within the limited time. By extension, it is possible to achieve an improvement in the yield at device manufacture, etc.

Although the invention made above by the present inventors has been described specifically on the basis of the preferred embodiments, the present invention is not limited to the embodiments referred to above, but may be changed in various ways within the scope not departing from the gist thereof. For example, the aforementioned embodiments have been described in detail to describe the present invention in a way easy to understand. They are not necessarily limited to one having all configurations described. Also, a part of the configuration of one embodiment may be replaced with the configuration of another embodiment. Further, the configuration of one embodiment may also be added with the configuration of another embodiment. Moreover, the addition/deletion/replacement of other configuration can be made to a part of the configuration of each embodiment.

1. A method for inspecting a mask pattern, comprising:
a first process of comparing a pattern to be inspected obtained by executing a lithography simulation on the mask pattern with a target pattern determined in advance to thereby extract a failure predicted spot as a detection point; and
a second process of providing a vertically long detection area centering on the detection point and a horizontally long detection area centering on the detection point for each detection point extracted in the first process, and categorizing a plurality of the detection points, based on the identity of patterns included in the vertically long detection area and the identity of patterns included in the horizontally long detection area,
wherein the vertically long detection area is a rectangular detection area longer in a vertical direction than in a horizontal direction, and
wherein the horizontally long detection area is a rectangular detection area longer in the horizontal direction than in the vertical direction.

2. The method according to claim 1,
wherein the second process includes:
a first step of categorizing the detection points, based on the identity of the patterns included in the vertically long detection area,
a second step of categorizing the detection points, based on the identity of the patterns included in the horizontally long detection area, and
a third step of classifying two arbitrary detection points classified into the same category in both of the first step and the second step into the same category and classifying two arbitrary detection points classified into another category in both of the first step and the second step into another category to thereby categorize the detection points eventually.

3. The method according to claim 1,
wherein in the second process, further, a square detection area centering on the detection point is provided for each detection point, and the detection points are categorized based on the identity of the patterns included in the vertically long detection area, the identity of the patterns included in the horizontally long detection area, and the identity of patterns included in the square detection area.

4. The method according to claim 3, wherein the second process includes:
a first step of categorizing the detection points, based on the identity of the patterns included in the vertically long detection area,
a second step of categorizing the detection points, based on the identity of the patterns included in the horizontally long detection area,
a third step of categorizing the detection points, based on the identity of the patterns included in the square detection area, and
a fourth step of classifying two arbitrary detection points classified into the same category in two or more of the first step, the second step, and the third step into the same category and classifying two arbitrary detection points classified into another category in the two or more steps into another category to thereby categorize the detection points eventually.

5. The method according to claim 1,
wherein the size of each of the vertically long detection area and the horizontally long detection area is five to ten times an “exposure wavelength/opening number” or a minimum pitch for a long side, and two to three times an exposure wavelength/opening number” or a minimum pitch for a short side.

6. A method for manufacturing a mask, comprising the steps of selecting a representative pattern for each category, based on categorized results obtained by the mask pattern inspecting method according to claim 1, and determining based on visual confirmation of the representative pattern whether the manufacture of the mask is advanced.

7. A method for manufacturing a semiconductor device, comprising the step of forming patterns in the semiconductor device by using a mask manufactured through the mask pattern inspecting method according to claim 1.

8. A method for inspecting a mask pattern, comprising:
a first process of comparing a pattern to be inspected obtained by executing a lithography simulation on the mask pattern with a target pattern determined in advance to thereby extract a failure predicted spot as a detection point; and
a second process of providing either one of a vertically long detection area centering on the detection point and a horizontally long detection area centering on the detection point for each detection point extracted in the first process, based on a circuitry feature of a circuit disposed at the detection point, and categorizing a plurality of the detection points, based on the identity of patterns included in the one detection area,
wherein the vertically long detection area is a rectangular detection area longer in a vertical direction than in a horizontal direction, and
wherein the horizontally long detection area is a rectangular detection area longer in the horizontal direction than in the vertical direction.

9. The method according to claim 8,
wherein in the second process, it is determined based on a correspondence relation between predetermined layout information of each circuit block and classification information of a detection area applied for each circuit block, whether the detection point is included in any of the respective circuit blocks, and the vertically long detection area and the horizontally long detection area are used properly for each detection point.

10. The method according to claim 8,
wherein the size of each of the vertically long detection area and the horizontally long detection area is five to ten times an “exposure wavelength/opening number” or a minimum pitch for a long side, and two to three times an exposure wavelength/opening number” or a minimum pitch for a short side.

11. A method for manufacturing a mask, comprising the steps of:
selecting a representative pattern for each category, based on categorized results obtained by the mask pattern inspecting method according to claim 8, and determining based on visual confirmation of the representative pattern whether the manufacture of the mask is advanced.

12. A method for manufacturing a semiconductor device, comprising the step of forming patterns in the semiconductor device by using a mask manufactured through the mask pattern inspecting method according to claim 8.

13. A method for inspecting a mask pattern, comprising:
a first process of comparing a pattern to be inspected obtained by executing a lithography simulation on the mask pattern with a target pattern determined in advance to hereby extract a failure predicted spot as a detection point; and
a second process of providing a detection area centering on the detection point for each detection point extracted in the first process, and categorizing a plurality of the detection points, based on the identity of patterns included in the detection area,
wherein the detection area has a shape in which a plurality of rectangles are superposed centering on the detection point and is comprised of stepwise sides extending in horizontal and vertical directions.

14. The method according to claim 13,
wherein the vertices of corners protruded toward the detection point side, which are formed with the stepwise sides are disposed together on the same circle centering on the detection point, and
wherein some of the stepwise sides are tangential lines of the same circle centering on the detection point.

15. The method according to claim 14,
wherein the rectangles are a vertically long rectangle longer in the vertical direction than in the horizontal direction, and a horizontally long rectangle longer in the horizontal direction than in the vertical direction, and
wherein the sizes of the vertically long rectangle and the horizontally long rectangle are both three to four times an “exposure wavelength/opening number” or a minimum pitch for long sides, and two to three times an “exposure wavelength/opening number” or a minimum pitch for short sides, and a size ratio between the long and short sides is √2.

16. The method according to claim 14,
wherein the detection area is applied where the mask pattern included in the detection area is a contact hole pattern.

17. A method for manufacturing a mask, comprising the step of selecting a representative pattern for each category, based on categorized results obtained by the mask pattern inspecting method according to claim 13, and determining based on visual confirmation of the representative pattern whether the manufacture of the mask is advanced.

18. A method for manufacturing a semiconductor device, comprising the step of forming patterns in the semiconductor device by using a mask manufactured through the mask pattern inspecting method according to claim 13.
